(19) United States
(12) Patent Application Publication
(10) Pub. No.: US 2012/0031458 A1
(43) Pub. Date: Feb. 9, 2012

(54) SOLAR CELL MODULE PROVIDED WITH AN EDGE SPACE

(75) Inventors: Hirofumi Nishi, Tokyo (JP); Hirohisa Suzuki, Tokyo (JP)

(73) Assignee: SHOWA SHELL SEKIYU K.K., Tokyo (JP)

(21) Appl. No.: 13/260,276

(22) PCT Filed: Apr. 16, 2010
(86) PCT No.: PCT/JP2010/056832

§ 371 Date: Sep. 24, 2011

(30) Foreign Application Priority Data
Apr. 17, 2009 (JP) 2009-100463

(51) Int. Cl. H01L 31/042

(52) U.S. Cl. 136/244

(57) ABSTRACT

The solar cell module having a preferable edge space that prevents characteristics of a solar cell such as conversion efficiency from being deteriorated without making processes complicated is provided. In a solar cell module including a substrate glass, a first layer formed on the substrate glass and a second layer formed on the first layer, the first layer is removed by a first removing means having a first energy amount to provide a first edge space in which the first layer is not formed between an end part of the first layer and an end part of the glass substrate, and the second layer is removed by a second removing means having a second energy amount to provide a second edge space in which the second layer is not formed between an end part of the second layer and the end part of the glass substrate. A width of the second edge space is larger than a width of the first edge space.

### TECHNICAL FIELD

The present invention relates to a technique regarding a solar cell module having an edge space, and more particularly relates to a CIS-based (a general name of a CuInSe₂-based including CIS, CIGS, CIGSS or the like) thin film solar cell module.

### BACKGROUND ART

Usually, in the CIS-based thin film solar cell module, layers including a metallic base electrode layer, a p type light absorbing layer, a high resistance buffer layer and an n type window layer (a transparent conductive film) are respectively laminated on the surface of a substrate (109) to form the CIS-based thin film solar cell module. A filler (103) having a sealing effect such as an EVA (Ethylene-Vinyl Acetate) resin, PVB (Polyvinyl Butyral), etc. is put thereon and cover glass (102) of an upper surface is laminated and attached thereon. The obtained solar cell module is surrounded by a frame (101) made of aluminum etc. to cover an end part of the solar cell module. Between the frame and the solar cell module, a resin is sandwiched (not shown in the drawing) to prevent moisture such as water from entering from the end part of the cover glass (102) and improve a weather resistance (see FIG. 1).

On the other hand, there is a frameless solar cell module to which an aluminum frame is not attached in order to lighten the solar cell module and reduce a production cost. As such a frameless solar cell module, a solar cell module that includes a light receiving surface side film, a light receiving surface side filler, a plurality of solar cell elements electrically connected together by connecting tabs, a back surface side filler and a back surface side film which are sequentially arranged so as to be piled, and has a structure in which a peripheral edge part of the light receiving surface side film is fusion welded to a peripheral edge part of the back surface side film is proposed (see patent document 1).

Further, as another frameless solar cell module, a structure in which when a frameless solar cell module is laid on a member to be attached such as a roof of a residence having a gradient, rod shaped joint fillers are held between the solar cell modules adjacent in the direction of the gradient of the member to be attached to lay the solar cell modules so that all the rod shaped joint fillers do not protrude from the surfaces of the solar cell modules is proposed (see patent document 2).

Further, a frameless solar cell module that has an edge space (a space where device layers are not piled) provided in a periphery of a solar cell circuit is also proposed (see FIG. 2 and patent document 3). When the edge space is provided, the frame does not need to be attached and a production cost can be more reduced and the solar cell module can be more lightened than the solar cell module of a type having the frame. As a manufacturing method of the solar cell module of this type, after a laminated film (a first electrode (108)/a semiconductor layer (107)/a second electrode (104)) is formed on the entire surface of a light receiving surface side of a substrate (109), the laminated film of an area corresponding to the edge space is removed by a laser or a sandblaster etc. to form the edge space (see FIG. 2). For instance, patent document 4 discloses a technique for removing a laminated film of an edge space area by using a YAG laser.

### BACKGROUND ART DOCUMENT

### Patent Documents

Patent Document 1: JP-A-2006-86390
Patent Document 2: JP-A-2002-322765
Patent Document 3: JP-A-2008-282944
Patent Document 4: JP-T-2002-540950

### SUMMARY OF THE INVENTION

### Problems that the Invention is to Solve

When the laminated film of the edge space part is removed, a problem arises that a performance (especially, conversion efficiency) of a solar cell circuit is deteriorated. Here, the solar cell circuit means the laminated film formed on the substrate before the edge space is formed and the cover glass is laminated. Now, a principle will be described below that the above-described problem arises in the case of a CIS-based thin film solar cell.

FIG. 3A is a plan view seen from a light receiving surface side of the CIS-based thin film solar cell. FIG. 3B is an enlarged sectional view of the CIS-based thin film solar cell in the direction perpendicular (a-a′ in FIG. 3A) to a division groove. As shown in FIG. 3A, the circuit is formed with a plurality of cells which are formed by dividing the semiconductor layer and the second electrode by a plurality of mutually parallel division grooves.

Here, when the edge space (a part surrounded by a dotted line in FIG. 3A) of an end part perpendicular to the division grooves is formed by the sandblaster, the laminated film may be damaged in an end part of the laminated film exposed to the edge space to deteriorate the conversion efficiency of the circuit. (Namely, after the edge space is formed, a boundary part to the edge space in the laminated film may be possibly damaged to deteriorate the conversion efficiency of the circuit.) Further, in a process by the sandblaster, as a further problem, a problem arises that cleaning up of sand is complicated after the laminated film is removed to increase the production cost.

On the other hand, when the laser is used in place of the sandblaster, the problem does not arise for the process of the sand. However, in order to remove the first electrode (an Mo layer), a strong laser equivalent to 430 W is necessary. Since the first electrode (the Mo layer) is stronger than a CIS layer or the second electrode, a weak laser required for removing the CIS layer or the second electrode cannot process the first electrode. As a result, when the edge space is formed by using the strong laser, the CIS layer or the second electrode may be molten in the end part of the laminated film exposed to the edge space to be shunted in the division groove parts. Owing to the shunt, a problem arises that the conversion efficiency of the solar cell circuit is deteriorated.

### Means for Solving the Problems

In order to solve the above-described problems, the solar cell module in the present invention has a preferable edge space that prevents characteristics of a solar cell such as conversion efficiency from being deteriorated without making processes complicated.

Namely, in a solar cell module including a substrate glass (409), a first layer (408) formed on the substrate glass (409) and a second layer (404, 405, 406) formed on the first layer (408), the first layer (408) is removed by a first removing means having a first energy amount to provide a first edge space in which the first layer (408) is not formed between an end part of the first layer (408) and an end part of the glass substrate, the second layer (404, 405, 406) is removed by a second removing means having a second energy amount to provide a second edge space in which the second layer (404, 405, 406) is not formed between an end part of the second layer (404, 405, 406) and the end part of the glass substrate (409), and a width of the second edge space is larger than a width of the first edge space.

Further, in a solar cell module according to a preferable aspect of the present invention, the second layer (404, 405, 406) is divided into a plurality of cells (302) by a plurality of division grooves (301) that divide the second layer (404, 405, 406) and the second edge space is formed so as to be perpendicular to the division grooves (301).

In a solar cell module according to a still another aspect of the present invention, the first layer (408) is harder than the second layer (404, 405, 406) and the second energy amount is smaller than the first energy amount.

In a solar cell module according to a still another aspect of the present invention, the first layer (408) includes a first electrode including molybdenum, and the second layer (404, 405, 406) includes: a CIS layer (406) formed on the first layer (408); a buffer layer (405) formed on the CIS layer (406); and a second electrode layer (404) formed on the buffer layer (405).

In a solar cell module according to a still another aspect of the present invention, the width of the first edge space is 10 mm or more and the width of the second edge space is larger by 0.1 mm or more than the width of the first edge space.

In a solar cell module according to a still further aspect of the present invention, the first removing means is a pulse laser or a sandblaster, and the second removing means is a pulse laser or a mechanical scribe.

### BRIEF DESCRIPTION OF THE DRAWINGS

FIG. 1A shows a plan view of a frame type solar cell module according to a conventional technique.

FIG. 1B shows an enlarged view (a front view) of a section of an end part of the frame type solar cell module according to the conventional technique.

FIG. 2 shows an enlarged view (a front view) of a section of an end part of a frameless type solar cell module according to a conventional technique.

FIG. 3A shows a plan view of the frameless type solar cell module according to the conventional technique.

FIG. 3B shows an enlarged view (a front view) of a section of an end part of the frameless type solar cell module according to the conventional technique.

FIG. 4A shows a plan view of a solar cell module of a preferable exemplary embodiment of the present invention.

FIG. 4B shows an enlarged view (a part of a front view) of a section of an end part seen from a direction parallel to division grooves in FIG. 4A.

FIG. 4C is a sectional view having a part of a side view in FIG. 4A enlarged.

FIG. 5A is one example of a sample device (before processing) that evaluates effects of the invention.

FIG. 5B is one example of the sample device (after the processing) that evaluates the effects of the invention.

FIG. 6A shows a sectional view (a front view) of a solar cell circuit according to a preferable embodiment of the present invention before forming an edge space.

FIG. 6B shows a sectional view (a front view) of the solar cell circuit according to the preferable embodiment of the present invention in which a second layer is removed.

FIG. 6C is a sectional view (a front view) of the solar cell module according to the preferable embodiment of the present invention to which an edge space process is applied.

FIG. 7A shows a sectional view of a solar cell circuit according to a preferable embodiment of the present invention before forming an edge space.

FIG. 7B shows a sectional view (a front view) of the solar cell circuit according to the preferable embodiment of the present invention in which a second edge space is formed.

FIG. 7C is a sectional view (a front view) of the solar cell module according to the preferable embodiment of the present invention to which an edge space process is applied.

FIG. 8A shows a sectional view of a solar cell circuit according to a preferable embodiment of the present invention before forming an edge space.

FIG. 8B shows a sectional view (a front view) of the solar cell circuit according to the preferable embodiment of the present invention in which a first edge space is formed.

FIG. 8C is a sectional view (a front view) of the solar cell module according to the preferable embodiment of the present invention to which an edge space process is applied.

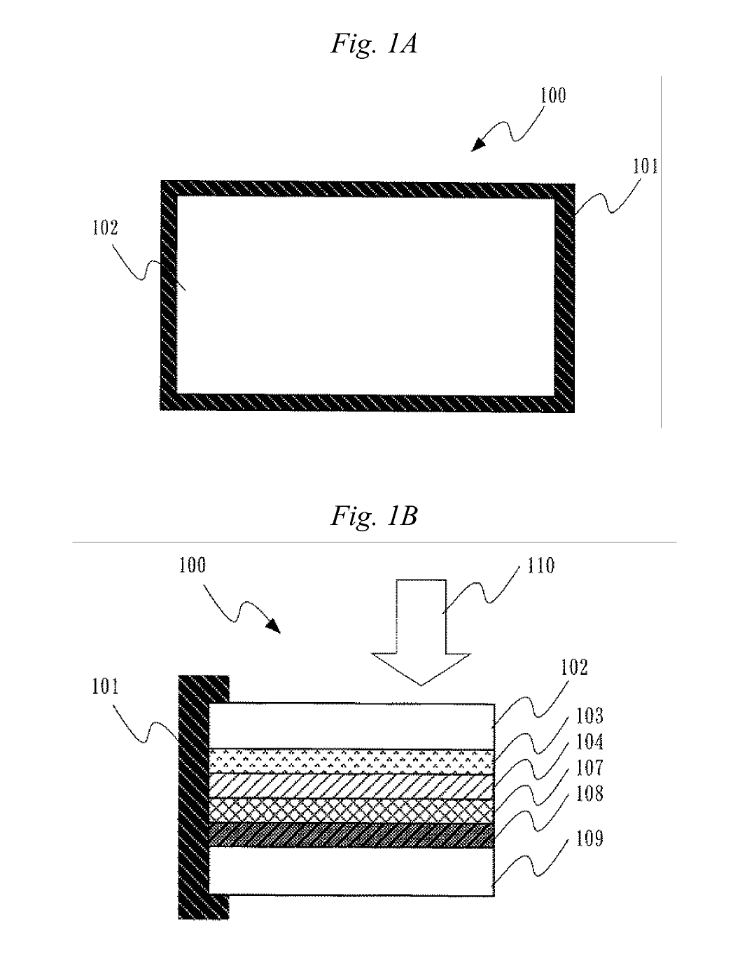

### MODE FOR CARRYING OUT THE INVENTION

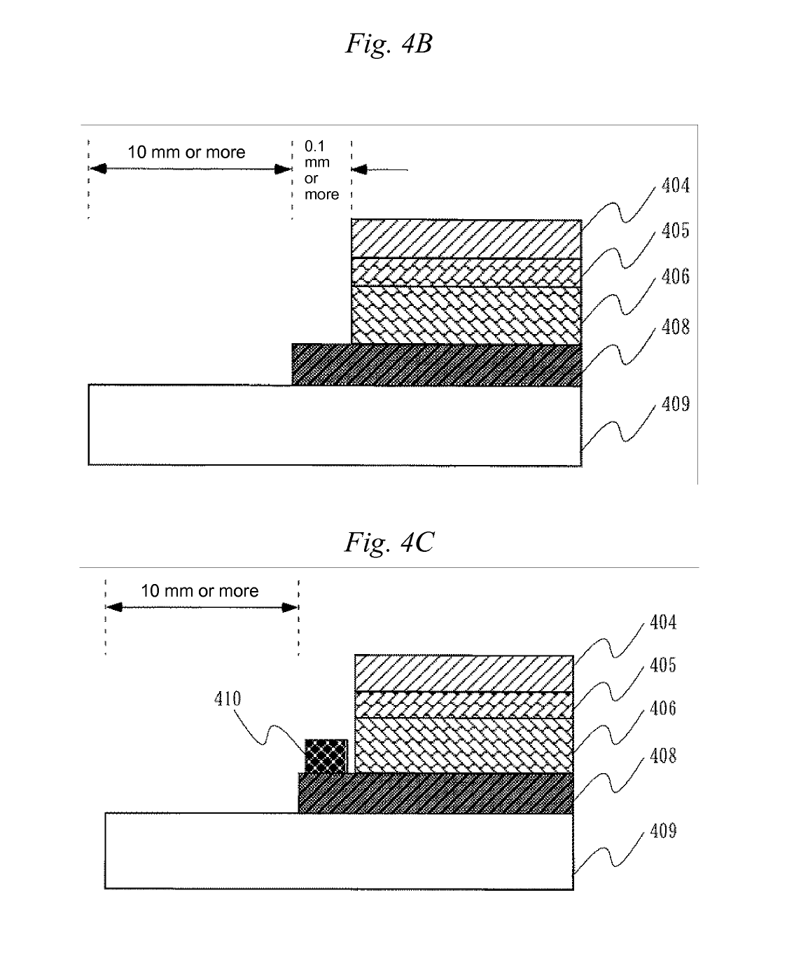

A solar cell circuit according to the present invention is shown in FIGS. 4A to 4C. FIG. 4A is a plan view seen from a light receiving surface side of a solar cell device. FIG. 4B is an enlarged view (a part of a front view) of a section of an end part seen from a direction parallel to division grooves. FIG. 4C is a sectional view having a part of a side view enlarged.

### <Manufacturing Method of Solar Cell Circuit According to the Present Invention>

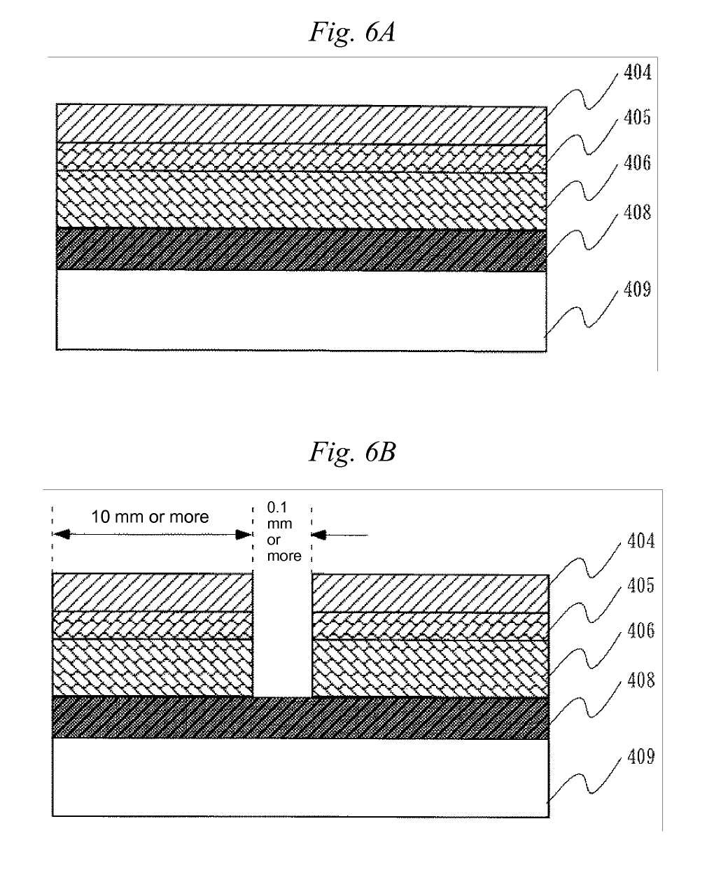

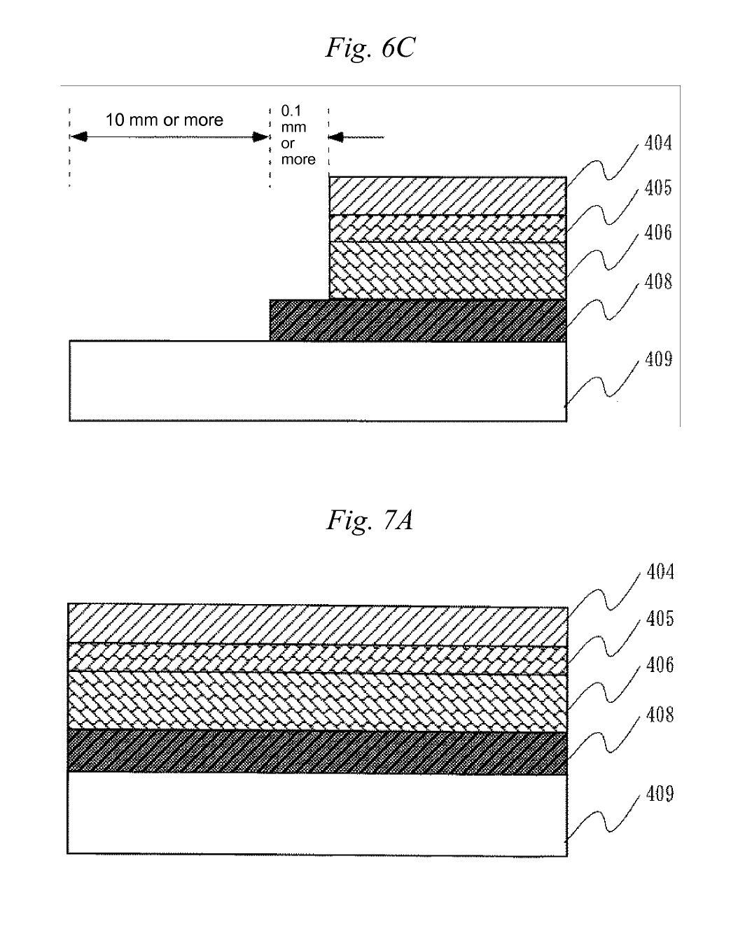

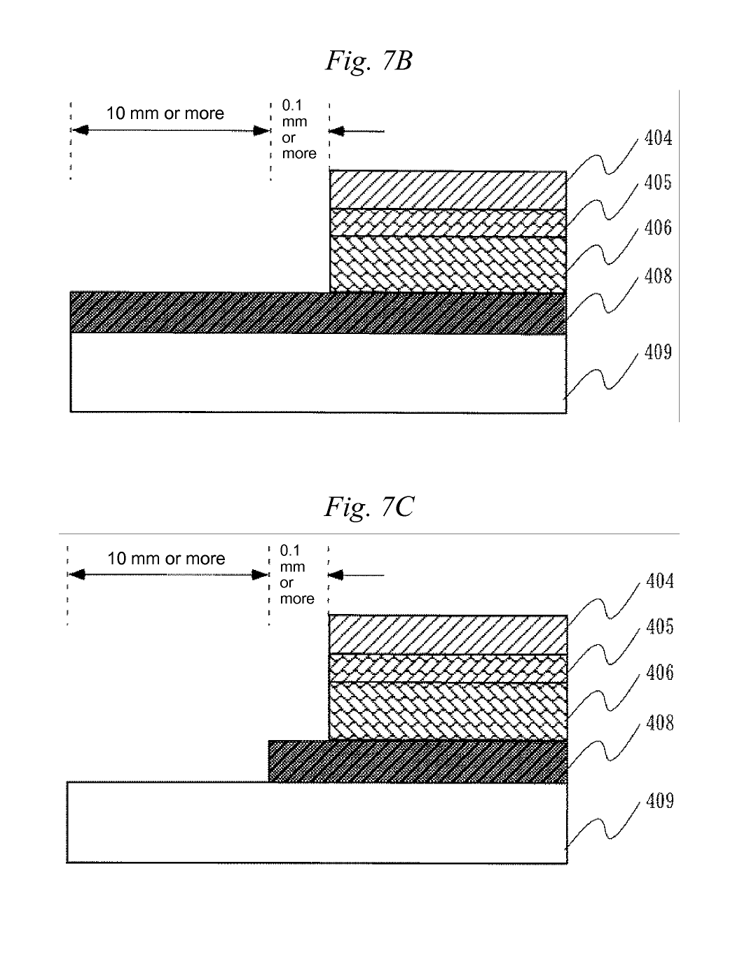

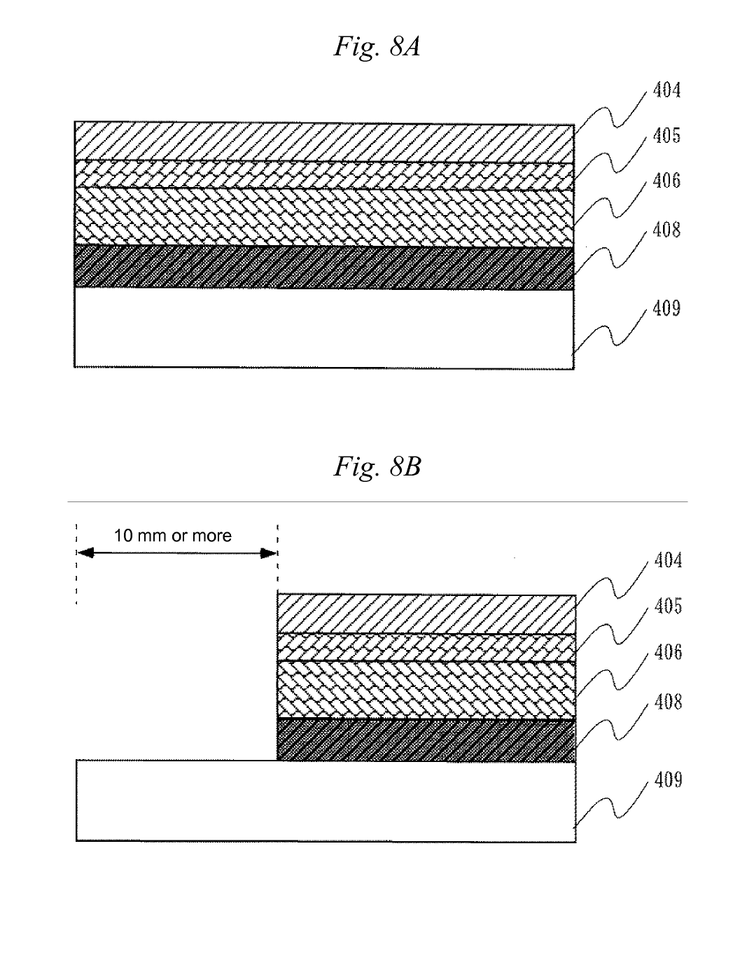

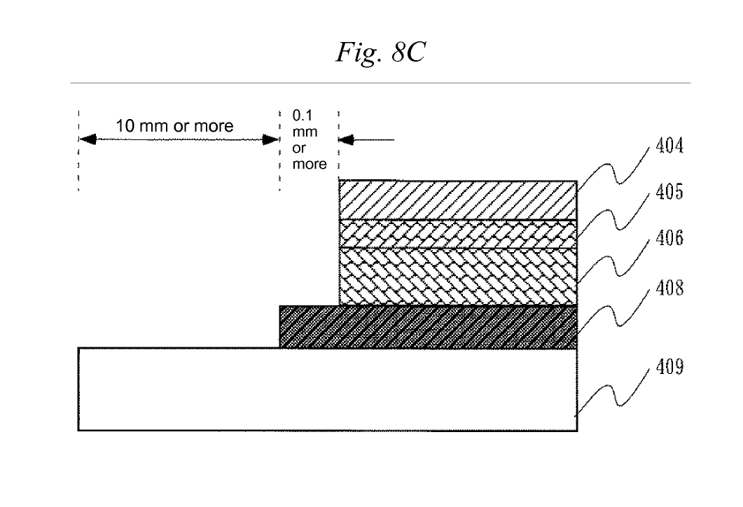

Now, a manufacturing method of a solar cell circuit according to a preferable embodiment of the present invention will be described below. FIG. 6A, FIG. 7A and FIG. 8A respectively show sectional views of solar cell circuits before forming an edge space. In the preferable embodiment, a first electrode (an Mo layer) (408) is formed on a glass substrate (409). A CIS layer (406), a buffer layer (405) and a second electrode (TCO) (404) are sequentially formed thereon. In other embodiments, a thin film solar cell including an amorphous silicon-based solar cell except the CIS-based solar cell may have the same constitution.

### (1) First Preferable Embodiment

Initially, a laser having weak energy is applied from the glass substrate side of such a solar cell circuit, thereby removing other layers than the first electrode (refer it also to as a “first layer” hereinafter) (408), that is, the CIS layer (406), the buffer layer (405) and the second electrode (404) (refer them also to as “second layers” or a “group of second layers”, hereinafter). A place to be removed by the irradiation of the laser is located inside by 10 mm or more from ends of the layers including the glass substrate (409) respectively and a removed width is preferably 0.1 to 1 mm or more (see FIG. 6B). As for the irradiation of the laser, a pulse laser is preferably used. When the layers respectively have the thickness of about 2 to 3 μm, other layers than the first electrode, that is, the second layers (404, 405, 406) can be removed by a pulse frequency of about 6 kHz and energy equivalent to 9 W. In another preferable embodiment, the laser is not applied from the glass substrate side and may be applied from the second electrode side. In a still another embodiment, the second layers (404, 405, 406) may be removed by a mechanical scribing including a knife in place of the weak laser.

The stronger first electrode (the Mo layer) (408) cannot be removed by applying the above-described laser having the weak energy. In order to remove the first electrode (408), a strong laser having the pulse frequency of about 6 kHz and equivalent to 430 W needs to be applied. When the laser of such a strong energy is applied to all the layers together, ends of the second layers (404, 405, 406) which are not stronger than the first electrode (408) may be damaged by the irradiation of the strong energy to deteriorate the conversion efficiency of the circuit.

Accordingly, as shown in FIG. 6C, the strong laser is applied to remove the first electrode in such a way that the first electrode (408) is left by 0.1 to 1 mm or more than the second layers (404, 405, 406) so as not to give an influence to the ends of the second layers (404, 405, 406). Since the strong laser is applied to such a position, the ends of the second layers (404, 405, 406) are not damaged due to the irradiation of the strong energy and the conversion efficiency of the circuit can be prevented from being deteriorated. Such a strong laser is preferably applied from the glass substrate side, however, the strong laser may be applied from the second electrode side. Consequently, a first edge space in which the first electrode (408) is not formed is provided with a width of 10 mm or more. Further, a second edge space in which the second layers (404, 405, 406) are not formed is provided with a width larger by 0.1 to 1 mm than the first edge space.

In other preferable embodiments, a sandblaster may be used in place of the strong pulse laser. When the sandblaster is used, the end parts of the second layers (404, 405, 406) exposed to the second edge space are preferably masked before a sandblaster process.

### (2) Second Preferable Embodiment

A laser having weak energy is applied from a glass substrate (409) side of a solar cell circuit shown in FIG. 7A, thereby removing other layers than a first electrode (408), that is, a CIS layer (406), a buffer layer (405) and a second electrode (404) by 10 mm or more from ends. Thus, an edge space (a second edge space) is formed. As for an irradiation of the laser, a pulse laser is preferably used similarly to the above-described first preferable embodiment. When the layers respectively have the thickness of about 2 to 3 μm, the second edge space can be formed by a pulse frequency of about 6 kHz and energy equivalent to 9 W. In another embodiment, the second edge space may be formed by a mechanical scribing including a knife in place of the weak laser.

As described above, the stronger first electrode (an Mo layer) (408) cannot be removed by applying the above-described laser having the weak energy. A strong laser having the pulse frequency of about 6 kHz and equivalent to 430 W is applied to subsequently remove the first electrode (408) and form a first edge space. In other preferable embodiment, a sandblaster may be used in place of the strong pulse laser. When the sandblaster is used, the end parts of the second layers (404, 405, 406) exposed to the second edge space are preferably masked before a sandblaster process.

In any cases, the first edge space is formed so that the first edge space has a width of 10 mm or more from the end of the glass substrate (409) and the width thereof is smaller by 0.1 to 1 mm or more than that of the second edge space. In other words, the second edge space is formed so that the second edge space has a width larger by 0.1 to 1 mm or more than that of the first edge space and the width of the second edge space is 10 mm or more.

### (3) Third Preferable Embodiment

A laser having strong energy is applied from a glass substrate (409) side of a solar cell circuit shown in FIG. 8A, thereby removing all laminated layers (a first electrode, a CIS layer, a buffer layer and a second electrode) by 10 mm or more from ends. Thus, a first edge space is formed (see FIG. 8B). As for an irradiation of the laser, a pulse laser is preferably used similarly to the above-described preferable embodiment. When the layers respectively have the thickness of about 2 to 3 μm, all the layers can be removed by a pulse frequency of about 6 kHz and energy equivalent to 430 W. In other preferable embodiment, a sandblaster may be used in place of the strong pulse laser. When the laser having the strong energy is applied to all the layers or the sandblaster is applied to all the layers, especially, ends of second layers (404, 405, 406) are damaged.

Then, as shown in FIG. 8C, a laser having weak energy is applied so that a second edge space is formed inside by 0.1 to 1 mm or more from the first edge space formed as described above. As for the irradiation of the weak laser, the pulse laser is preferably used similarly to the above-described preferable embodiment. When the layers respectively have the thickness of about 2 to 3 μm, other layers than the first electrode (408), that is, the second layers (404, 405, 406) can be removed by a pulse frequency of about 6 kHz and energy equivalent to 9 W. In another preferable embodiment, the laser is not applied from the glass substrate side and may be applied from the second electrode side. In a still another embodiment, the second layers (404, 405, 406) may be removed by a mechanical scribing including a knife in place of the weak laser.

In any cases, the first edge space is formed so that the first edge space has a width of 10 mm or more from the end of the glass substrate and the width thereof is smaller by 0.1 to 1 mm or more than that of the second edge space. In other words, the second edge space is formed so that the second edge space has a width larger by 0.1 to 1 mm or more than that of the first edge space and the width of the second edge space is 10 mm or more.

### <Evaluation>

Now, influences that the solar cell circuits according to the present invention which are formed by the above-described preferable embodiments give to conversion efficiency by carrying out the above-described processes will be evaluated as described below.

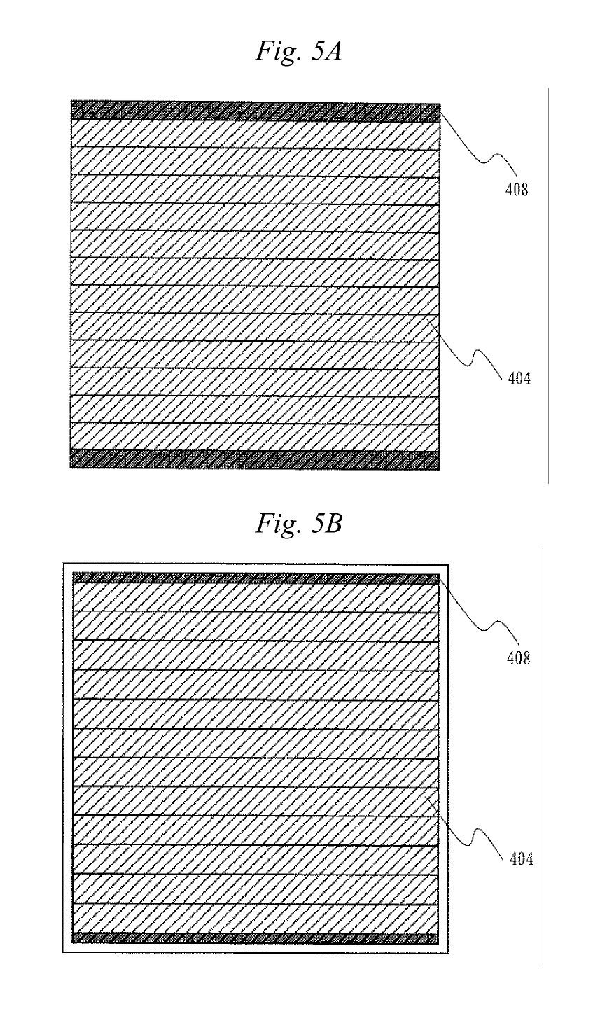

FIG. 5A shows one example of a plan view of a solar cell before an edge space process. FIG. 5B shows one example of a plan view of the solar cell after the edge space process. In any of cases, the solace cell having a dimension of 30 cm×30 cm is used.

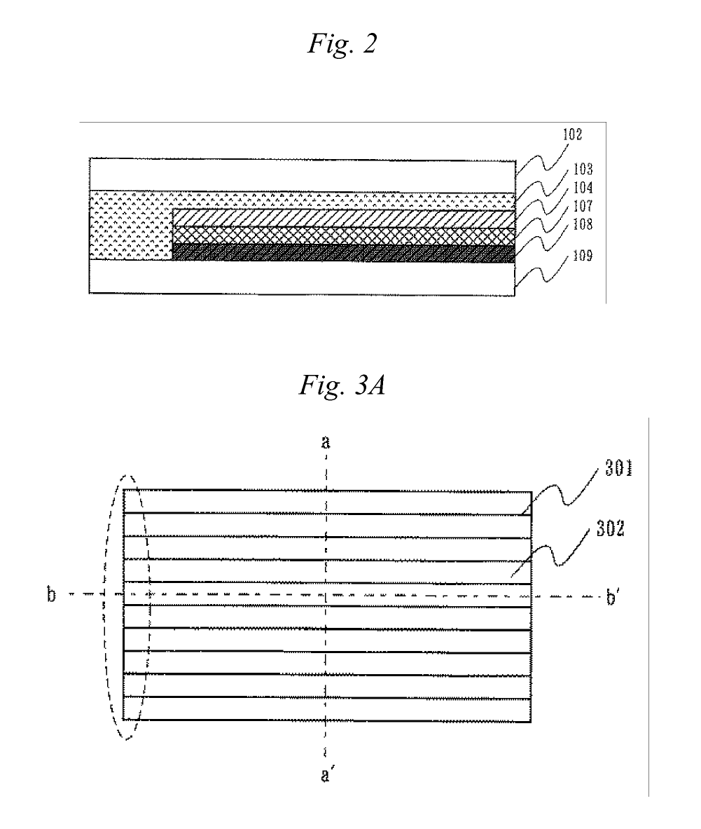

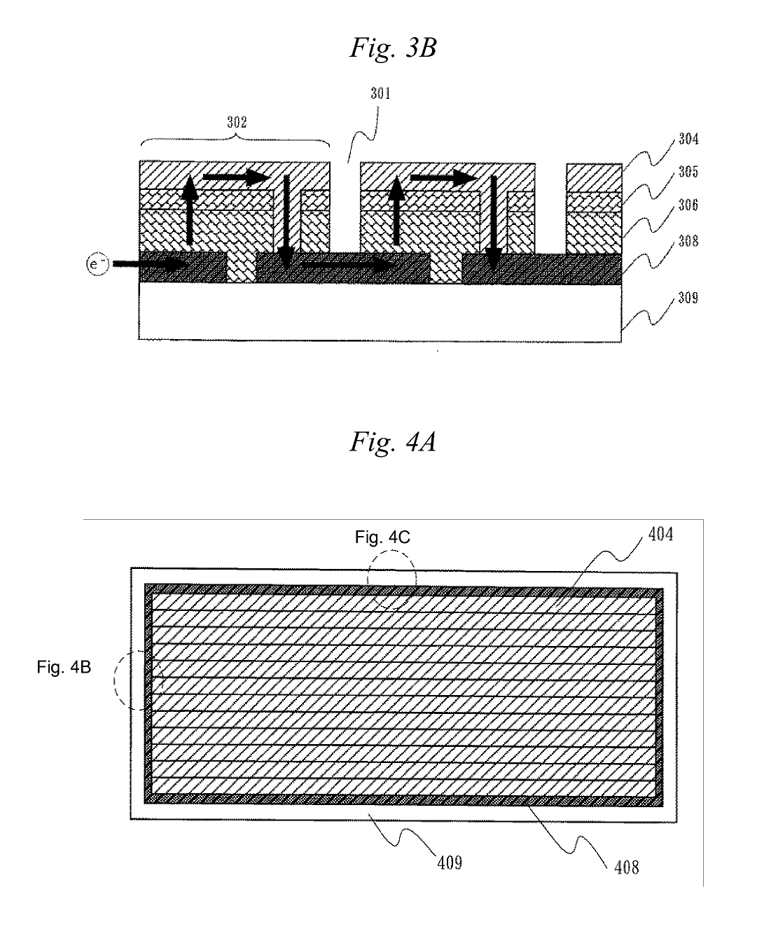

As shown in FIG. 2 as a conventional technique, the solar cell that has the same width of the first edge space as the width of the second edge space, namely, a sample device 6 and a sample device 7 that have been processed to a state shown in FIG. 8B were prepared, and results are shown in Table 1 which were obtained by measuring E_{FF} (conversion efficiency) and FF (Fill Factor) before and after carrying out the process shown in FIG. 8B.

TABLE 1

| Evaluation item | | Device 6 | Device 7 |
|---|---|---|---|
| E_{FF} | Before process | 12.945 | 13.749 |
| | After process | 12.248 | 12.021 |
| | Ratio of change | 0.946 | 0.874 |
| FF | Before process | 0.615 | 0.658 |
| | After process | 0.592 | 0.594 |
| | Ratio of change | 0.963 | 0.903 |

As compared therewith, as samples obtained by carrying out the processes in the present invention, namely, the samples formed in such a way that the second edge space is formed so as to have a width larger by 0.1 to 1 mm or more than that of the first edge space and the width of the edge space is 10 mm or more, devices 1 to 4 were prepared. Results are shown in Table 2 which were obtained by measuring E_{FF} (conversion efficiency) and FF (Fill Factor) before and after carrying out the processes according to the present invention.

TABLE 2

| Evaluation item | | Device 1 | Device 2 | Device 3 | Device 4 |
|---|---|---|---|---|---|
| E_{FF} | Before | 12.581 | 12.506 | 12.865 | 13.273 |
| | process | | | | |
| | After | 12.736 | 12.485 | 12.813 | 13.291 |
| | process | | | | |
| | Ratio of | 1.012 | 0.998 | 0.996 | 1.001 |
| | change | | | | |
| FF | Before | 0.618 | 0.613 | 0.625 | 0.641 |
| | process | | | | |
| | After | 0.619 | 0.611 | 0.622 | 0.639 |
| | process | | | | |
| | Ratio of | 1.002 | 0.997 | 0.995 | 0.997 |
| | change | | | | |

In any of the samples, the laser was applied from the glass substrate side. In the sample devices 6 and 7, a process of applying the pulse laser having 6 kHz and 430 W was carried out to remove all the layers. In the sample devices 1 to 4, the pulse laser having 6 kHz and 430 W is used to form the first edge space and the pulse laser having 6 kHz and 9 W is used to form the edge space.

It can be recognized that the ratios of change of the device 1 to the device 4 are more greatly improved than those of the conventional process in any of the items E_{FF} and FF. In the conventional process, the ends of the second layers (404, 405, 406) are supposed to be damaged by the irradiation of the strong laser. However, since the second edge space is provided by applying the weak laser in the present invention, the damaged ends of the second layers (404, 405, 406) are removed, which is supposed to be a great factor for reducing a trouble such as a shunt in the division grooves.

### DESCRIPTION OF THE REFERENCE NUMERALS AND SIGNS

100 solar cell module
101 frame
102 cover glass
103 filler
104 second electrode (TCO)
107 semiconductor layer (buffer layer+CIS layer)
108 first electrode (Mo layer)
109 substrate
110 solar light
301 division groove
302 cell
304 second electrode (TCO)
305 buffer layer
306 CIS layer
308 first electrode (Mo layer)
309 glass substrate
404 second electrode (TCO)
405 buffer layer
406 CIS layer
408 first electrode (Mo layer)
409 glass substrate
410 ribbon wire

1-8. (canceled)

9. A solar cell module comprising:
a substrate glass;
a first layer formed on the substrate glass and
a second layer formed on the first layer,
wherein the first layer is removed by a first removing means having a first energy amount to provide a first edge space in which the first layer is not formed between an end part of the first layer and an end part of the glass substrate,
the second layer is removed by a second removing means having a second energy amount to provide a second edge space in which the second layer is not formed between an end part of the second layer and the end part of the glass substrate,
a width of the second edge space is larger than a width of the first edge space,
the second layer is divided into a plurality of cells by a plurality of division grooves that divide the second layer,
the second edge space is formed so as to be perpendicular to the division grooves,
the first edge space is formed so as to be perpendicular to the division grooves,
the first layer is harder than the second layer, and
the second energy amount is smaller than the first energy amount.

10. A solar cell module according to claim 9, wherein the first layer comprises a first electrode including molybdenum.

11. A solar cell module according to claim 9, wherein the second layer comprises:
a CIS layer formed on the first layer;
a buffer layer formed on the CIS layer; and
a second electrode layer formed on the buffer layer.

12. A solar cell module according to claim 9, wherein the width of the first edge space is 10 mm or more and the width of the second edge space is larger by 0.1 mm or more than the width of the first edge space.

13. A solar cell module according to claim 9, wherein the first removing means is a pulse laser or a sandblaster.

14. A solar cell module according to claim 9, wherein the second removing means is a pulse laser or a mechanical scribe.
